(19) United States
(12) Patent Application Publication
(10) Pub. No.: US 2020/0266307 A1
(43) Pub. Date: Aug. 20, 2020

(54) HIGH EFFICIENCY SOLAR CELL WITH LIGHTWEIGHT SUPPORT STRUCTURE AND METHOD OF MANUFACTURING THE SAME

(71) Applicant: DY Semiconductor Technology Co., Ltd., Fuzhou (CN)

(72) Inventors: Defu YI, Hsinchu City (TW); Ding-Yuan CHEN, Hsinchu City (TW)

(21) Appl. No.: 16/277,074

(22) Filed: Feb. 15, 2019

(51) Int. Cl. H01L 31/0224; H01L 31/0687; H01L 31/048; H01L 31/0304

(52) U.S. Cl. CPC H01L 31/022425; H01L 31/03046; H01L 31/048; H01L 31/06875

(57) ABSTRACT

A solar cell with lightweight support structure and a method of manufacturing the same are provided. The solar cell includes: a composite substrate; a photoelectric conversion structure disposed on the composite substrate, and including a light receiving side and a back side which is opposite the light receiving side; a front electrode formed on the light receiving side; and a back electrode formed on the back side, where the composite substrate includes an optical reflective layer which is connected with the back side of the photoelectric conversion structure; and where the photoelectric conversion structure includes at least one Group III-V compound semiconductor layer.

### FIELD OF DISCLOSURE

The present disclosure relates to a solar cell and a method of manufacturing the same, and more particularly to a high efficiency solar cell with lightweight support structure and a method of manufacturing the same.

### BACKGROUND

In solar cells industry, among the wide range of semiconductor materials for solar cells currently under intensive study, those using Group III-V compound semiconductor materials have exhibited the highest efficiencies. Moreover, Group III-V multi junction solar cells have experienced vast improvements in efficiency over decades of technological progress. The substrate material should be selected to be lattice-matched to the deposited semiconductor material. For example, Group III-V multi junction solar cells may be grown on a Ge or GaAs substrate that is lattice-matched to the deposited Group III-V semiconductor alloy materials of the device.

However, many of the substrate materials, such as GaP, GaAs, GaAsP, and InAs, that are lattice-matched to desirable Group III-V semiconductor materials may be relatively rare or prohibitively expensive, or may be difficult to obtain or produce in large quantities or suitable sizes. Also, these substrates are relatively heavy and thick, thereby hindering their commercialization.

Accordingly, it is necessary to provide Group III-V compound semiconductor solar cells with low-cost, lightweight, and high efficiency to solve the technical problems in the prior art.

### SUMMARY OF THE DISCLOSURE

In order to solve the above-mentioned technical problems, an object of the present disclosure is to provide a high efficiency solar cell with lightweight support structure, in which a Group III-V photoelectric conversion structure is disposed on a lightweight and flexible composite substrate. Also, a Group III-V based substrate could be recycled for the next usage as a growth template, thereby obtaining Group III-V compound semiconductor solar cells with low-cost and lightweight. Moreover, since the composite substrate includes an optical reflective layer, it enhances efficiency by enabling photon recycling.

In order to achieve the above object, the present disclosure provides a solar cell with lightweight support structure, including: a composite substrate; a photoelectric conversion structure disposed on the composite substrate, and including a light receiving side and a back side which is opposite the light receiving side; a front electrode formed on the light receiving side; and a back electrode formed on the back side, where the composite substrate includes an optical reflective layer which is connected with the back side of the photoelectric conversion structure; and where the photoelectric conversion structure includes at least one Group III-V compound semiconductor layer.

In one preferable embodiment of the present disclosure, the composite substrate includes a polymer support substrate and the optical reflective layer which is disposed on the polymer support substrate.

In one preferable embodiment of the present disclosure, the polymer support substrate is flexible.

In one preferable embodiment of the present disclosure, the at least one Group III-V compound semiconductor layer is selected from a group consisting of a GaAs layer, an InGaP layer, and an InGaAs layer.

In one preferable embodiment of the present disclosure, the back electrode partially covers the back side of the photoelectric conversion structure.

In one preferable embodiment of the present disclosure, a material of the optical reflective layer is selected from the group consisting of aluminum and silver.

In one preferable embodiment of the present disclosure, a surface of the optical reflective layer adjacent to the photoelectric conversion structure is a textured surface for light trapping.

In one preferable embodiment of the present disclosure, the solar cell further includes an adhesive layer disposed between the photoelectric conversion structure and the composite substrate.

In one preferable embodiment of the present disclosure, the optical reflective layer itself is adhesive, such that the photoelectric conversion structure is adhered to the composite substrate by the optical reflective layer.

Another object of the present disclosure is to provide a method of manufacturing a solar cell with lightweight support structure, including: forming a photoelectric conversion structure, where the photoelectric conversion structure includes a light receiving side and a back side which is opposite the light receiving side; providing a composite substrate; and disposing the photoelectric conversion structure on the composite substrate, where the composite substrate includes an optical reflective layer which is connected with the back side of the photoelectric conversion structure; and where the photoelectric conversion structure includes at least one Group III-V compound semiconductor layer.

In one preferable embodiment of the present disclosure, the step of forming the photoelectric conversion structure includes: providing a Group III-V based substrate; forming a sacrificial layer on the Group III-V based substrate; and growing the photoelectric conversion structure on the sacrificial layer.

In one preferable embodiment of the present disclosure, the step of disposing the photoelectric conversion structure on the composite substrate includes: transferring the photoelectric conversion structure onto the composite substrate from the Group III-V based substrate.

In one preferable embodiment of the present disclosure, the step of disposing the photoelectric conversion structure on the composite substrate includes: disposing the Group III-V based substrate with the sacrificial layer and the photoelectric conversion structure on the composite substrate, where the photoelectric conversion structure is contacted with the composite substrate; separating the Group III-V based substrate from the photoelectric conversion structure by removing the sacrificial layer.

In one preferable embodiment of the present disclosure, the step of growing the photoelectric conversion structure on the sacrificial layer includes: sequentially growing an InGaP layer, a GaAs layer, and an InGaAs layer on the sacrificial layer.

In one preferable embodiment of the present disclosure, a material of the sacrificial layer includes AlAs.

In one preferable embodiment of the present disclosure, the method further includes: forming a front electrode on the light receiving side; and forming a back electrode on the back side, where the back electrode partially covers the back side of the photoelectric conversion structure.

In one preferable embodiment of the present disclosure, the step of disposing the photoelectric conversion structure on the composite substrate includes: disposing an adhesive layer on the composite substrate, and connecting the photoelectric conversion structure with the composite substrate by the adhesive layer.

In one preferable embodiment of the present disclosure, the optical reflective layer itself is adhesive, such that after disposing the photoelectric conversion structure on the composite substrate, the photoelectric conversion structure is adhered to the composite substrate by the optical reflective layer.

In the solar cell of the present disclosure, a photoelectric conversion structure is transferred onto a lightweight and flexible composite substrate from a Group III-V based substrate where the photoelectric conversion structure is grown on, such that the removed Group III-V based substrate can be recyclable for the next usage as a growth template. Furthermore, since the composite substrate includes an optical reflective layer, it enhances efficiency by enabling photon recycling. Therefore, a light-absorption of the solar cell at wavelengths below 600 nm can be increased.

### BRIEF DESCRIPTION OF THE DRAWINGS

In order to more clearly describe the technical solutions of the embodiments of the present disclosure, accompanying drawings to be used in the detailed description of the disclosure will be briefly described hereinbelow. Obviously, the accompanying drawings described hereinbelow only illustrate some of the embodiments of the present disclosure, and those of ordinary skill in the art can also obtain other accompanying drawings therefrom without the need of making inventive efforts.

FIG. 1A to FIG. 1E are a series of structural diagrams showing manufacturing steps for forming a solar cell according a first preferable embodiment of the present disclosure.

FIG. 2 is a graphical diagram showing the calculated reflectance spectra from the solar cell of FIG. 1E.

FIG. 3 is a structural diagram showing a solar cell according a second preferable embodiment of the present disclosure.

### DETAILED DESCRIPTION

The following clearly and completely describes the technical solutions in the embodiments of the present disclosure with reference to the accompanying drawings in the embodiments of the present disclosure. Apparently, the embodiments to be described are merely part rather than all of the embodiments of the present disclosure. All other embodiments obtained by persons of ordinary skill in the art based on the embodiments of the present disclosure without creative efforts shall fall within the protection scope of the present disclosure.

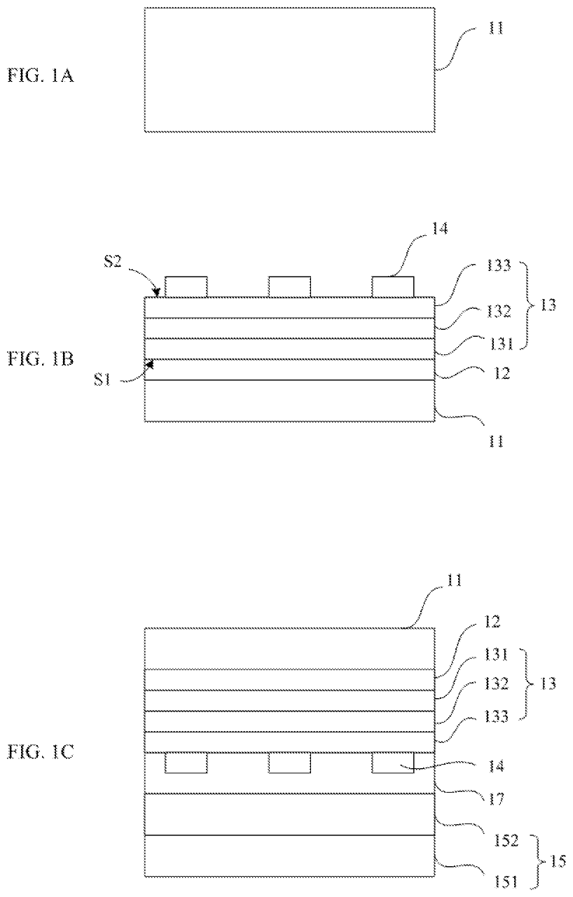

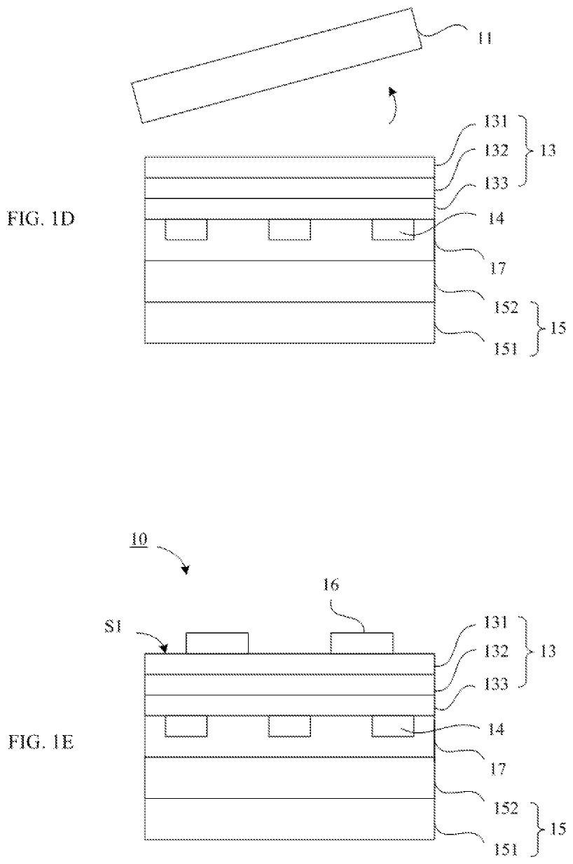

Refer to FIG. 1A to FIG. 1E, which are a series of structural diagrams showing manufacturing steps for forming a solar cell 10 according a first preferable embodiment of the present disclosure. Firstly, as shown in FIG. 1A, a Group III-V based substrate 11 is provided. A material of the Group III-V based substrate 11 is preferably selected to be lattice-matched to a sequentially deposited semiconductor material, and may be GaP, GaAs, GaAsP, and InAs, that are lattice-matched to Group III-V semiconductor materials.

After the Group III-V based substrate 11 is provided, as shown in FIG. 1B, a sacrificial layer 12 and a photoelectric conversion structure 13 are sequentially formed on the Group III-V based substrate 11, where a material of the sacrificial layer 12 may be AlAs, and the photoelectric conversion structure 13 is made of Group III-V semiconductor materials. Moreover, in the first preferable embodiment, the solar cell 10 is a triple junction solar cell, where the photoelectric conversion structure 13 includes a top layer 131, a middle layer 132, and a bottom layer 133. For example, the photoelectric conversion structure 13 is formed by sequentially growing an InGaP layer (i.e. the top layer 131), a GaAs layer (i.e. the middle layer 132), and an InGaAs layer (i.e. the bottom layer 133) on the sacrificial layer 12. It should be noted that, in other embodiments, the solar cell of the present disclosure may be a single junction solar cell or a multi junction solar cell, such that the photoelectric conversion structure may include at least one Group III-V compound semiconductor layer.

Additionally, the photoelectric conversion structure 13 includes a light receiving side S1 for receiving sunlight and a back side S2 which is opposite the light receiving side S1. As shown in FIG. 1B, the light receiving side S1 is located on the top layer 131, and the back side S2 is located on bottom layer 133. Moreover, a back electrode 14 is formed on the back side S2 of the photoelectric conversion structure 13, which is an ideal ohmic contact electrode with high light reflectivity. Preferably, the back electrode 14 is patterned, that is, the back electrode 14 partially covers the back side S2 of the photoelectric conversion structure 13, thereby decreasing light absorption by the back electrode 14.

After the photoelectric conversion structure 13 is formed, the photoelectric conversion structure 13 is transferred onto a composite substrate 15 from the Group III-V based substrate 11. In one exemplary embodiment, the transferring steps are described as follow.

As shown in FIG. 1C, the composite substrate 15 is provided. The composite substrate 15 includes a polymer support substrate 151 and an optical reflective layer 152 which is disposed on the polymer support substrate 151. Preferably, the polymer support substrate 151 is lightweight and flexible, and may be made of polyimide, PET, etc. A material of the optical reflective layer 152 may be selected from the group consisting of aluminum, silver, and so on. Furthermore, in the other embodiments, a surface of the optical reflective layer adjacent to the photoelectric conversion structure 13 may be a textured surface for increasing light trapping property.

As shown in FIG. 1C, the Group III-V based substrate 11, the sacrificial layer 12, and the photoelectric conversion structure 13 are disposed on the composite substrate 15, where the optical reflective layer 152 is connected with back side S2 of the photoelectric conversion structure 13. For example, an adhesive layer 17 may be firstly formed on the optical reflective layer 152 of the composite substrate 15, and then the back side S2 of the photoelectric conversion structure 13 is adhered on the composite substrate 15 via the adhesive layer 17, i.e. the adhesive layer 17 will be disposed between the photoelectric conversion structure 13 and the composite substrate 15. Also, the adhesive layer may be made of silver paste.

After disposing the photoelectric conversion structure 13 on the composite substrate 15, as shown in FIG. 1D, the Group III-V based substrate 11 is separated from the photoelectric conversion structure 13 by removing the sacrificial layer 12 through a lift-off process, such as an epitaxial lift off (ELO) process, a laser lift-off process, etc. For example, the sacrificial layer 12 can be destroyed by performing an etch process using hydrofluoric acid. It should be note that, in the present disclosure, the removed Group III-V based substrate 11 can be recyclable for the next usage as a growth template, such that manufacture cost of the solar cells is thus reduced.

After removing the Group III-V based substrate 11, as shown in FIG. 1E, a front electrode 16 is formed on the light receiving side S1 of the photoelectric conversion structure 13. Therefore, the solar cell 10 is produced.

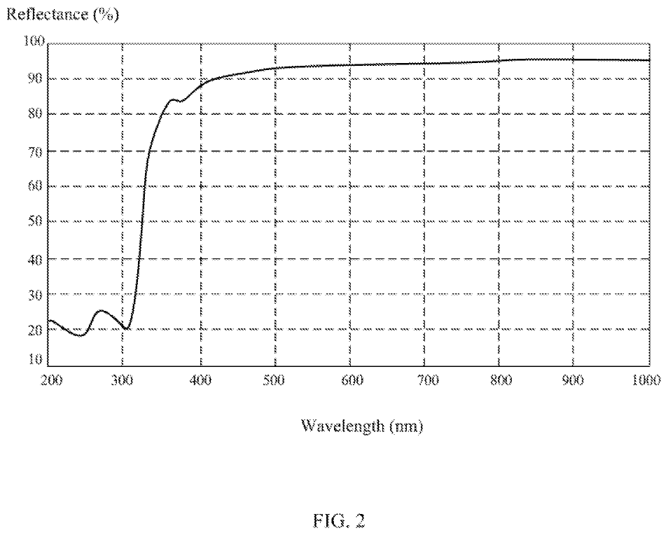

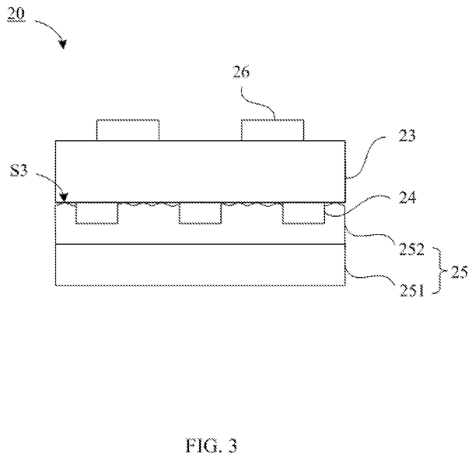

Refer to FIG. 2, which depicts a graphical diagram depicting reflectance (%) vs. wavelength (nm) of the solar cell 10 described above. In the solar cell 10 of the present disclosure, since the composite substrate 15 includes the optical reflective layer 152, a light-absorption of the solar cell at wavelengths below 600 nm can be increased. Accordingly, the present disclosure enhances photoelectric efficiency by increasing the utilization of photons for generating electricity. It should be understood that crystalline semiconductor materials, such as the Group III-V compound semiconductor materials, cannot be grown on noncrystalline substrates, such as the composite substrate 15. This direct growth scheme would inevitably result in poor-performance amorphous cells. Thus, in the present disclosure, the production of the Group III-V compound semiconductor materials on the noncrystalline composite substrate 15 can be prepared by transferring at least one Group III-V compound semiconductor layer grown in advance on proper crystalline Group III-V based substrate 11 onto the noncrystalline composite substrate 15.

Refer to FIG. 3, which is a structural diagram showing a solar cell 20 according a second preferable embodiment of the present disclosure. The solar cell 20 includes a photoelectric conversion structure 23, a back electrode 24, a front electrode 26, and a composite substrate 25. The back electrode 24 and the front electrode 26 are respectively formed on two opposite side of the photoelectric conversion structure 23. The composite substrate 25 includes a polymer support substrate 251 and an optical reflective layer 252 which is disposed on the polymer support substrate 251. The photoelectric conversion structure 23 may include at least one Group III-V compound semiconductor layer, but it is not limited thereto. The manufacturing steps of forming the photoelectric conversion structure 23 and transferring the photoelectric conversion structure 23 onto the composite substrate 25 are similar to the first preferable embodiment of the present disclosure, so an explanation in this regard will not be provided again. Also, materials of the photoelectric conversion structure 23 and the composite substrate 25 may select from as mentioned in the first embodiment of the present disclosure, it will not repeat again.

As shown in FIG. 3, a surface S3 of the optical reflective layer adjacent to the photoelectric conversion structure 23 is a textured surface S3, such that it is capable of improving light trapping property. Also, in comparison to the first preferable embodiment, the photoelectric conversion structure 23 is directly adhered to the composite substrate 25, instead of connecting via an additional adhesive layer. Specifically, the optical reflective layer 252 of the composite substrate 25 itself is adhesive, so that after disposing the photoelectric conversion structure 23 on the composite substrate 25, the photoelectric conversion structure 23 will be adhered to the composite substrate 25 by the optical reflective layer 252. Therefore, a thinner solar cell 20 can be manufactured. Also, manufacture cost of the solar cells is reduced, since the additional adhesive layer is omitted.

In the solar cell of the present disclosure, a photoelectric conversion structure is transferred onto a lightweight and flexible composite substrate from a Group III-V based substrate where the photoelectric conversion structure is grown on, such that the removed Group III-V based substrate can be recyclable for the next usage as a growth template, thereby reducing the manufacture cost. Furthermore, since the composite substrate includes an optical reflective layer, it enhances photoelectric efficiency.

The above descriptions are merely preferable embodiments of the present disclosure, and are not intended to limit the scope of the present disclosure. Any modification or replacement made by those skilled in the art without departing from the spirit and principle of the present disclosure should fall within the protection scope of the present disclosure. Therefore, the protection scope of the present disclosure is subject to the appended claims.

What is claimed is:

1. A solar cell with lightweight support structure, comprising:
a composite substrate;
a photoelectric conversion structure disposed on the composite substrate, and comprising a light receiving side and a back side which is opposite the light receiving side;
a front electrode formed on the light receiving side; and
a back electrode formed on the back side;
wherein the composite substrate comprises an optical reflective layer which is connected with the back side of the photoelectric conversion structure; and
wherein the photoelectric conversion structure comprises at least one Group III-V compound semiconductor layer.

2. The solar cell with lightweight support structure as claimed in claim 1, wherein the composite substrate comprises a polymer support substrate and the optical reflective layer which is disposed on the polymer support substrate.

3. The solar cell with lightweight support structure as claimed in claim 2, wherein the polymer support substrate is flexible.

4. The solar cell with lightweight support structure as claimed in claim 1, wherein the at least one Group III-V compound semiconductor layer is selected from a group consisting of a GaAs layer, an InGaP layer, and an InGaAs layer.

5. The solar cell with lightweight support structure as claimed in claim 1, wherein the back electrode partially covers the back side of the photoelectric conversion structure.

6. The solar cell with lightweight support structure as claimed in claim 1, wherein a material of the optical reflective layer is selected from the group consisting of aluminum and silver.

7. The solar cell with lightweight support structure as claimed in claim 1, wherein a surface of the optical reflective layer adjacent to the photoelectric conversion structure is a textured surface for light trapping.

8. The solar cell with lightweight support structure as claimed in claim 1, further comprising an adhesive layer disposed between the photoelectric conversion structure and the composite substrate.

9. The solar cell with lightweight support structure as claimed in claim 1, wherein the optical reflective layer itself is adhesive, such that the photoelectric conversion structure is adhered to the composite substrate by the optical reflective layer.

10. A method of manufacturing a solar cell with lightweight support structure, comprising:
forming a photoelectric conversion structure, wherein the photoelectric conversion structure comprises a light receiving side and a back side which is opposite the light receiving side;
providing a composite substrate; and
disposing the photoelectric conversion structure on the composite substrate;
wherein the composite substrate comprises an optical reflective layer which is connected with the back side of the photoelectric conversion structure; and
wherein the photoelectric conversion structure comprises at least one Group III-V compound semiconductor layer.

11. The method of manufacturing a solar cell with lightweight support structure as claimed in claim 10, wherein the composite substrate comprises a polymer support substrate and the optical reflective layer which is disposed on the polymer support substrate.

12. The method of manufacturing a solar cell with lightweight support structure as claimed in claim 10, wherein the polymer support substrate is flexible.

13. The method of manufacturing a solar cell with lightweight support structure as claimed in claim 11, wherein the step of forming the photoelectric conversion structure comprising:
providing a Group III-V based substrate;
forming a sacrificial layer on the Group III-V based substrate; and
growing the photoelectric conversion structure on the sacrificial layer.

14. The method of manufacturing a solar cell with lightweight support structure as claimed in claim 13, wherein the step of disposing the photoelectric conversion structure on the composite substrate comprising:
transferring the photoelectric conversion structure onto the composite substrate from the Group III-V based substrate.

15. The method of manufacturing a solar cell with lightweight support structure as claimed in claim 13, wherein the step of disposing the photoelectric conversion structure on the composite substrate comprising:
disposing the Group III-V based substrate with the sacrificial layer and the photoelectric conversion structure on the composite substrate, wherein the photoelectric conversion structure is contacted with the composite substrate;
separating the Group III-V based substrate from the photoelectric conversion structure by removing the sacrificial layer.

16. The method of manufacturing a solar cell with lightweight support structure as claimed in claim 13, wherein the step of growing the photoelectric conversion structure on the sacrificial layer comprising:
sequentially growing an InGaP layer, a GaAs layer, and an InGaAs layer on the sacrificial layer.

17. The method of manufacturing a solar cell with lightweight support structure as claimed in claim 13, wherein a material of the sacrificial layer comprises AlAs.

18. The method of manufacturing a solar cell with lightweight support structure as claimed in claim 10, further comprising:
forming a back electrode on the back side, wherein the back electrode partially covers the back side of the photoelectric conversion structure; and
forming a front electrode on the light receiving side.

19. The method of manufacturing a solar cell with lightweight support structure as claimed in claim 10, wherein the step of disposing the photoelectric conversion structure on the composite substrate comprising:
disposing an adhesive layer on the composite substrate, and
connecting the photoelectric conversion structure with the composite substrate by the adhesive layer.

20. The method of manufacturing a solar cell with lightweight support structure as claimed in claim 10, wherein the optical reflective layer itself is adhesive, such that after disposing the photoelectric conversion structure on the composite substrate, the photoelectric conversion structure is adhered to the composite substrate by the optical reflective layer.
